(19) United States
(12) Patent Application Publication
(10) Pub. No.: US 2026/0303103 A1
(43) Pub. Date: Oct. 1, 2026

(54) DIFFERENTIAL CHARGE PUMP

(71) Applicant: International Business Machines Corporation, Armonk, NY (US)

(72) Inventors: James STROM, Rochester, MN (US); Douglas ZUERCHER, Rochester, MN (US); Ann Chen WU, Hopewell Junction, NY (US); John BORKENHAGEN, Rochester, MN (US)

(21) Appl. No.: 19/092,364

(22) Filed: Mar. 27, 2025

(51) Int. Cl. H03L 7/089; H03F 3/45

(52) U.S. Cl. CPC H03L 7/0896; H03F 3/45654

(57) ABSTRACT

The present disclosure describes a differential charge pump that includes a first switching circuit, a second switching circuit, a first current source, a second current source, a third current source, a first amplifier, and a second amplifier. The first switching circuit produces a first output (FILT). The second switching circuit produces a second output (FILTN) and a third output (SENSEN). The first current source is electrically connected to a first port of the first switching circuit. The second current source is electrically connected to a second port of the first switching circuit. The third current source is electrically connected to the second switching circuit. The first amplifier controls the second current source and the third current source based on FILTN and SENSEN. The second amplifier controls the first current source based on FILT and FILTN.

### BACKGROUND

The present disclosure relates to charge pumps, and more specifically, to a differential charge pump.

### SUMMARY

The present disclosure describes a differential charge pump. According to an embodiment, the differential charge pump includes a first switching circuit, a second switching circuit, a first current source, a second current source, a third current source, a first amplifier, and a second amplifier. The first switching circuit produces a first output (FILT). The second switching circuit produces a second output (FILTN) and a third output (SENSEN). The first current source is electrically connected to a first port of the first switching circuit. The second current source is electrically connected to a second port of the first switching circuit. The third current source is electrically connected to the second switching circuit. The first amplifier controls the second current source and the third current source based on FILTN and SENSEN. The second amplifier controls the first current source based on FILT and FILTN. Other embodiments include a method performed by the differential charge pump and a system (e.g., a phase locked loop) that includes the differential charge pump.

### BRIEF DESCRIPTION OF THE DRAWINGS

FIG. 1 illustrates an example system for producing an oscillating signal.

FIG. 2 illustrates an example charge pump in the system of FIG. 1.

FIG. 3 illustrates example components of the charge pump of the system of FIG. 1.

FIG. 4 illustrates an example averaging circuit in the system of FIG. 1.

FIG. 5 is a flowchart of an example method performed by the system of FIG. 1.

### DETAILED DESCRIPTION

A phase locked loop is a circuit that adjusts an output signal such that the output signal has a frequency that matches or approximates the frequency of an input or reference signal. The phase locked loop may be used in applications including signal generators, clock generators, modulators/demodulators, etc. One of the components of the phase locked loop is a charge pump that produces a control signal based on discrepancies between the frequency of a reference signal and the frequency of an output of an oscillator. The control signal from the charge pump controls the oscillator to adjust the frequency of the output of the oscillator. When the frequency of the output of the oscillator matches the frequency of the reference signal, the charge pump may stop adjusting the control signal. In some instances, the phase locked loop may include other circuitry (e.g., frequency division circuits) that operate on the output of the oscillator, and the charge pump may adjust the frequency of the output of the oscillator until the frequency of the output of the other circuitry matches the frequency of the reference signal.

Some phase locked loops use a differential charge pump that outputs differential output signals to control the oscillator. The voltage difference between the differential output signals may be used to control the oscillator. The differential output signals may be complementary signals. As a result, the differential output signals may have voltages that move in tandem such that the differential output signals remain centered around a particular voltage, which may also be referred to as the common mode voltage. Additionally, noise may be common to both differential output signals, so subtracting the differential output signals to determine the voltage difference between the differential output signals may remove or reduce the effects of noise from impacting the oscillator.

Existing phase locked loops use oscillators that operate with particular common mode voltages. These phase locked loops, however, may experience difficulty preventing the common mode voltage of the differential charge pump from drifting or moving, which may cause the oscillators to function improperly or incorrectly. Some phase locked loops may use one or more amplifiers that directly control the output signals of the charge pump to maintain the common mode voltage. These amplifiers, however, may consume a large amount of electrical power and be susceptible to or cause electromigration to occur in the phase locked loops. Additionally, because these amplifiers may consume large amounts of power, capacitors that stabilize these amplifiers also occupy a large amount of integrated circuit area.

The present disclosure describes a differential charge pump that uses amplifiers to control gates of transistors in the current sources of the charge pump. The charge pump may include first and second current sources for a first switching circuit and third and fourth current sources for a second switching circuit. The first switching circuit produces output signals that are referred to as FILT and SENSE. The second switching circuit produces output signals that are referred to as FILTN and SENSEN, which are complementary to FILT and SENSE, respectively. FILT and FILTN may be used to control other components (e.g., an oscillator of a phase locked loop). Additionally, FILT, FILTN, and SENSE and/or SENSEN may be used to control the operation of the charge pump. For example, the charge pump may include an amplifier that produces a control signal based on FILTN and SENSEN, and this control signal controls the gates of transistors in the second current source and the third current source to reduce a difference between FILTN and SENSEN. The charge pump may also include another amplifier that produces a control signal based on an average of FILT and FILTN (which may be the common mode voltage of the charge pump). This control signal controls the gates of transistors in the first current source to reduce a difference between the common mode voltage and a reference common mode voltage.

In certain embodiments, the differential charge pump provides several technical advantages. For example, by controlling the gates of transistors in the current sources, the differential charge pump may consume less electrical power relative to existing charge pumps. Additionally, the differential charge pump may be less susceptible to electromigration effects. Moreover, the differential charge pump may be smaller than existing charge pumps (e.g., due to the smaller capacitor that stabilizes the amplifiers).

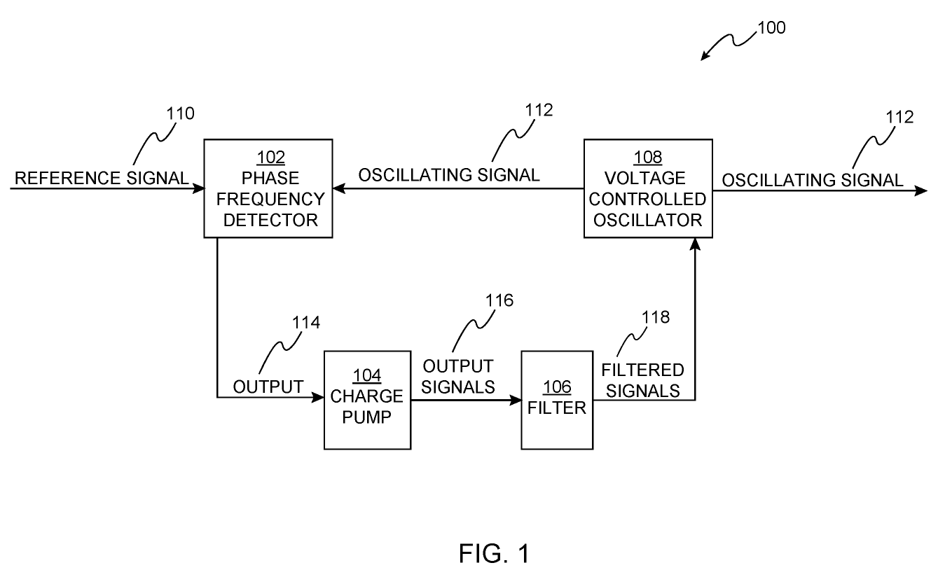

FIG. 1 illustrates an example system 100 for producing an oscillating signal, which may be a phase locked loop. As seen in FIG. 1, the system 100 includes a phase frequency detector 102, a charge pump 104, a filter 106, and a voltage controlled oscillator 108. Generally, the system 100 produces an oscillating signal with a frequency that matches or approximates the frequency of a reference signal.

The phase frequency detector 102 determines whether there is a discrepancy between the frequency of a reference signal 110 and the frequency of an oscillating signal 112 produced by the voltage controlled oscillator 108. For example, the phase frequency detector 102 may subtract the oscillating signal 112 and the reference signal 110 to produce an output 114. The output 114 may include peaks or spikes indicating discrepancies between the reference signal 110 and the oscillating signal 112. The phase frequency detector 102 directs the output 114 to the charge pump 104.

The charge pump 104 produces one or more output signals 116 based on the output 114. For example, the charge pump 104 may be a differential charge pump that produces differential output signals 116 to control the voltage controlled oscillator 108. The voltage difference between the differential output signals 116 may be used to control the voltage controlled oscillator 108. The charge pump 104 may use the output signals 116 to adjust the oscillating signal 112 produced by the voltage controlled oscillator 108 such that the frequency of the oscillating signal 112 is brought closer to the frequency of the reference signal 110. As the frequency of the oscillating signal 112 is brought closer to the frequency of the reference signal 110, the output 114 produced by the phase frequency detector 102 may have fewer peaks or spikes. When the charge pump 104 removes the peaks or spikes from the output 114, the charge pump 104 may stop adjusting the output signals 116 and the voltage controlled oscillator 108.

The filter 106 may filter the output signals 116 from the charge pump 104 to produce filtered signals 118. By filtering the output signals 116, the filter 106 may remove some of the jitter from the output signals 116, which may smooth the output signals 116 before the output signals 116 are used to control the voltage controlled oscillator 108.

The voltage controlled oscillator 108 produces the oscillating signal 112 according to the output signals 116 and/or the filtered signals 118. Generally, the frequency of the oscillating signal 112 may be adjusted by adjusting the voltage difference between the output signals 116 from the charge pump 104. For example, increasing the voltage difference may increase the frequency of the oscillating signal 112, and reducing the voltage difference may reduce the frequency of the oscillating signal 112. Generally, the oscillating signal 112 is directed back to the phase frequency detector 102. The phase frequency detector 102 may then update the output 114 based on discrepancies between the oscillating signal 112 and the reference signal 110. The charge pump 104 may then adjust the output signals 116 to continue reducing the difference between the oscillating signal 112 and the reference signal 110. When the oscillating signal 112 has the same frequency as the reference signal 110, the charge pump 104 may stop adjusting the output signals 116 such that the voltage controlled oscillator 108 maintains the oscillating signal 112.

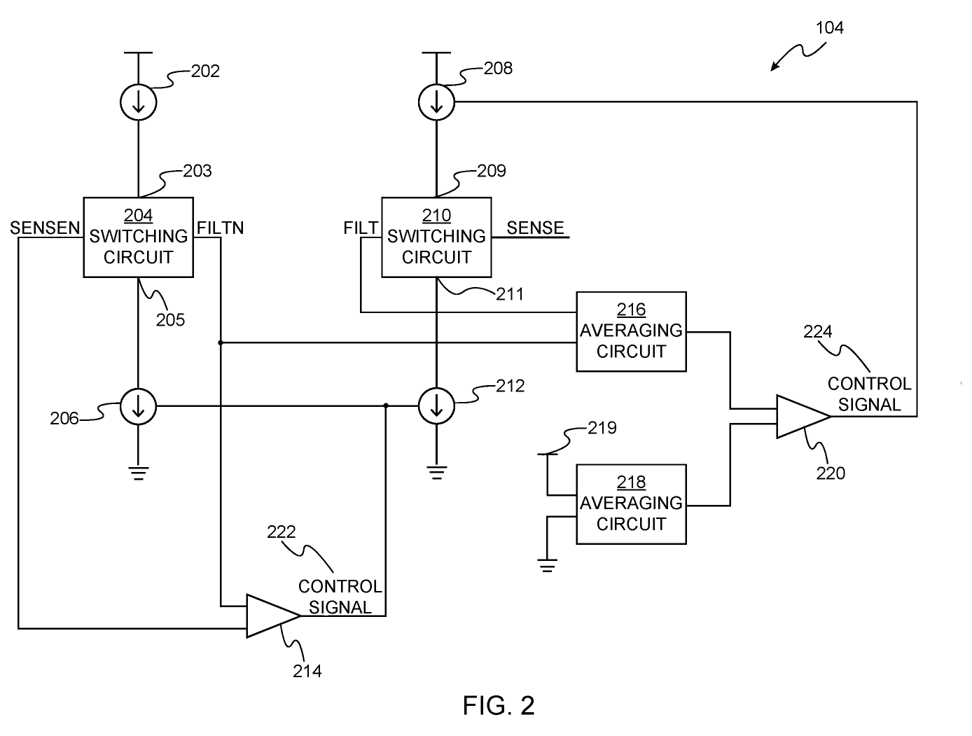

FIG. 2 illustrates an example charge pump 104 in the system 100 of FIG. 1. Generally, the charge pump 104 is a differential charge pump that produces two output signals (labeled FILT and FILTN) used to control the voltage controlled oscillator. As seen in FIG. 2, the charge pump 104 includes a current source 202, a switching circuit 204, a current source 206, a current source 208, a switching circuit 210, a current source 212, an amplifier 214, an averaging circuit 216, an averaging circuit 218, and an amplifier 220.

The current sources 202 and 206 are electrically connected to the switching circuit 204 at two different ports. The current source 202 may be connected to a port 203 of the switching circuit 204, and the current source 206 may be connected to a port 205 of the switching circuit 205. The switching circuit 204 produces two output signals (e.g., voltage signals) labeled FILTN and SENSEN. The current source 202 may direct an electrical current to the switching circuit 204 (e.g., a charging mode) when the switching circuit 204 is operated to increase the voltage of FILTN. The current source 206 may direct an electrical current away from the switching circuit 204 (e.g., a discharging mode) when the switching circuit 204 is operated to decrease the voltage of FILTN.

The switching circuit 204 includes switches (e.g., transistor switches) that can be operated to cause the switching circuit 204 to increase a voltage of FILTN or to cause the switching circuit 204 to decrease a voltage of FILTN. For example, a capacitor (not illustrated) coupled to FILTN may charge when the switching circuit 204 directs electric current to the capacitor using the current source 202, which may increase the voltage of FILTN. Conversely, the capacitor may discharge when the switching circuit 204 directs electric current away from the capacitor using the current source 206, which may decrease the voltage of FILTN.

Similarly, the switching circuit 204 includes switches (e.g., transistor switches) that can be operated to cause the switching circuit 204 to increase a voltage of SENSEN or to cause the switching circuit 204 to decrease a voltage of SENSEN. For example, a capacitor (not illustrated) coupled to SENSEN may charge when the switching circuit 204 directs electric current to the capacitor using the current source 202, which may increase the voltage of SENSEN. Conversely, the capacitor may discharge when the switching circuit 204 directs electric current away from the capacitor using the current source 206, which may decrease the voltage of SENSEN.

The current sources 208 and 212 are electrically connected to the switching circuit 210 at two different ports. The current source 208 may be connected to a port 209 of the switching circuit 210, and the current source 212 may be connected to a port 211 of the switching circuit 210. The switching circuit 210 produces two output signals (e.g., voltage signals) labeled FILT and SENSE, which may be complementary signals to FILTN and SENSEN, respectively. FILT and FILTN may change with respect to each other by the same magnitude but with opposite polarity, and SENSE and SENSEN may change with respect to each other by the same magnitude but with opposite polarity. As an example, if FILT were to increase by ten millivolts, then FILTN would decrease by ten millivolts. Similarly, if SENSE were to decrease by five millivolts, then SENSEN would increase by five millivolts. Generally, signals from a phase frequency detector (e.g., the phase frequency detector 102) along with the inverse of those signals may be directed to the switching circuits 204 and 210 to cause FILT to be complementary to FILTN and SENSE to be complementary to SENSEN. The current source 208 may direct an electrical current to the switching circuit 210 (e.g., a charging mode) when the switching circuit 210 is operated to increase the voltage of FILT. The current source 212 may direct an electrical current away from the switching circuit 210 (e.g., a discharging mode) when the switching circuit 210 is operated to decrease the voltage of FILT. In some embodiments, the current sources 208 and 212 may be formed using metal-oxide-semiconductor field-effect transistors (e.g., n-channel field-effect transistors).

The switching circuit 210 includes switches (e.g., transistor switches) that can be operated to cause the switching circuit 210 to increase a voltage of FILT or to cause the switching circuit 210 to decrease a voltage of FILT. For example, a capacitor (not illustrated) coupled to FILT may charge when the switching circuit 210 directs electric current to the capacitor using the current source 208, which may increase the voltage of FILT. Conversely, the capacitor may discharge when the switching circuit 210 directs electric current away from the capacitor using the current source 212, which may decrease the voltage of FILT.

Similarly, the switching circuit 210 includes switches (e.g., transistor switches) that can be operated to cause the switching circuit 210 to increase a voltage of SENSE or to cause the switching circuit 210 to decrease a voltage of SENSE. For example, a capacitor (not illustrated) coupled to SENSE may charge when the switching circuit 210 directs electric current to the capacitor using the current source 208, which may increase the voltage of SENSE. Conversely, the capacitor may discharge when the switching circuit 210 directs electric current away from the capacitor using the current source 212, which may decrease the voltage of SENSE.

The amplifier 214 receives FILTN and SENSEN as inputs from the switching circuit 204. The amplifier 214 then produces a control signal 222 that is directed to the current sources 206 and 212. In some embodiments, the control signal 222 is directed to gates of transistors in the current sources 206 and 212. In this manner, the amplifier 214 controls the operation of the current sources 206 and 212 by controlling the gates of the transistors in the current sources 206 and 212. Specifically, the amplifier 214 controls the operation of the current source 206 to reduce a difference between FILTN and SENSEN, which may cause FILTN and SENSEN to match. Additionally, the amplifier 214 controls the operation of the current source 212 to reduce a difference between FILT and SENSE.

The averaging circuit 216 receives FILT and FILTN from the switching circuits 204 and 210. The averaging circuit 216 may include a resistor network that produces an output that is the average of FILT and FILTN, which may also be the common mode voltage of the charge pump 104. The averaging circuit 218 receives two input signals, and the averaging circuit 218 may include a resistor network that produces an output that is the average of the two input signals. This output may function as the reference common mode voltage for the charge pump 104. In the example of FIG. 2, the averaging circuit 218 receives the signal from a power supply 219 for the charge pump 104 and electrical ground as two input signals. As a result, the averaging circuit 218 produces an output that is half the signal from the power supply as the reference common mode voltage. In some embodiments, the averaging circuit 216 and/or 218 may have a high input impedance to avoid loading FILT and/or FILTN.

The amplifier 220 receives the outputs of the averaging circuits 216 and 218. The amplifier 220 then produces a control signal 224 that is directed to the current source 208. In some embodiments, the control signal 224 is directed to gates of transistors in the current source 208. In this manner, the amplifier 220 controls the operation of the current source 208 by controlling the gates of the transistors in the current source 208. Specifically, the amplifier 220 controls the operation of the current source 208 to reduce a difference between the outputs of the averaging circuits 216 and 218, which may cause the outputs of the averaging circuits 216 and 218 to match. Stated differently, the amplifier 220 controls the operation of the current source 208 such that the common mode voltage of the charge pump 104 (indicated by the output of the averaging circuit 216) is brought closer to or matches the reference common mode voltage (indicated by the output of the averaging circuit 218). In this manner, the charge pump 104 prevents or keeps the common mode voltage of the charge pump 104 from drifting to a point where the voltage controlled oscillator stops functioning correctly.

The charge pump 104 may produce FILT and FILTN as complementary output signals for controlling the voltage controlled oscillator. For example, FILT and FILTN may charge or discharge capacitors such that the capacitors produce voltages to control the voltage controlled oscillator. The difference in the voltages may be used to adjust the oscillating signal produced by the voltage controlled oscillator. Increasing or decreasing the difference in the voltages may adjust the frequency of the oscillating signal.

In certain embodiments, because the control signal 222 and the control signal 224 are directed to gates of transistors in the current sources 206, 208, and 212, the charge pump 104 uses less power relative to existing charge pumps. Additionally, the charge pump 104 may experience less electromigration effects relative to existing charge pumps. Moreover, the charge pump 104 may occupy less area than existing charge pumps.

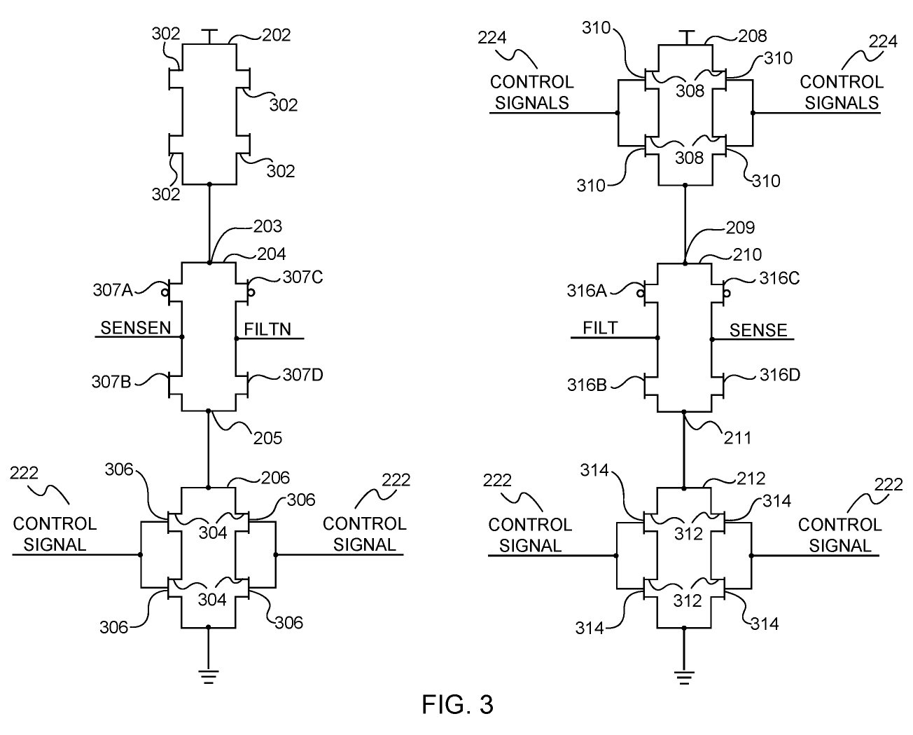

FIG. 3 illustrates example components of the charge pump of the system 100 of FIG. 1. As seen in FIG. 3, the charge pump includes the current source 202, which is connected to a power supply for the charge pump and to the port 203 of the switching circuit 204. The current source 202 includes transistors 302, which may be operated to direct an electrical current from the power supply to the switching circuit 204. Similarly, the charge pump includes the current source 206, which is connected to the port 205 of the switching circuit 204 and to electrical ground. The current source 206 includes transistors 304 with gates 306. The transistors 304 may be operated to direct an electrical current from the switching circuit 204 to electrical ground.

The switching circuit 204 is connected to the current source 202 and the current source 206. The switching circuit 204 includes transistors 307A, 307B, 307C, and 307D, which may be operated to place the switching circuit 204 in one of two different modes. In a charging mode, the transistors 307A, 307B, 307C, and 307D may be operated such that the switching circuit 204 directs an electrical current from the current source 202 to FILTN and SENSEN. In a discharging mode, the transistors 307A, 307B, 307C, and 307D may be operated such that the switching circuit 204 directs an electrical current from FILTN and SENSEN to the current source 206.

The charge pump also includes the current source 208, which is connected to the power supply and to the port 209 of the switching circuit 210. The current source 208 includes transistors 308 with gates 310. The transistors 308 may be operated to direct an electrical current from the power supply to the switching circuit 210. Similarly, the charge pump includes the current source 212, which is connected to the port 211 of the switching circuit 210 and to electrical ground. The current source 212 includes transistors 312 with gates 314. The transistors 312 may be operated to direct an electrical current from the switching circuit 210 to electrical ground.

The switching circuit 210 is connected to the current source 208 and the current source 212. The switching circuit 210 includes transistors 316A, 316B, 316C, and 316D, which may be operated to place the switching circuit 210 in one of two different modes. In the charging mode, the transistors 316A, 316B, 316C, and 316D may be operated such that the switching circuit 210 directs an electrical current from the current source 208 to FILT and SENSE. In the discharging mode, the transistors 316A, 316B, 316C, and 316D may be operated such that the switching circuit 210 directs an electrical current from FILT and SENSE to the current source 212.

As seen in FIG. 3, the control signal 222 is directed to the gates 306 of the transistors 304 in the current source 206 and to the gates 314 of the transistors 312 in the current source 212. In this manner, the control signal 222 controls the operation of the current sources 206 and 212. As discussed with respect to FIG. 2, the control signal 222 controls the operation of the current sources 206 and 212 to reduce a difference between SENSEN and FILTN produced by the switching circuit 204. As a result, the control signal 222 controls the gates 306 and 314, which may cause SENSEN to match FILTN.

Additionally, the control signal 224 is directed to the gates 310 of the transistors 308 in the current source 208. In this manner, the control signal 224 controls the operation of the current source 208. As discussed with respect to FIG. 2, the control signal 224 controls the operation of the current source 208 to reduce a difference between the common mode voltage of the charge pump (e.g., the average of FILT and FILTN) and a reference common mode voltage. As a result, the control signal 224 controls the gates 310, which may cause the common mode voltage of the charge pump to match the reference common mode voltage. In this manner, the charge pump may prevent or keep the common mode voltage of the charge pump from drifting.

The signals FILT and FILTN may be output from the charge pump to control the voltage controlled oscillator. For example, FILT and FILTN may be directed to capacitors to charge or discharge the capacitors, which changes the voltage at FILT and FILTN. The difference between these voltages is used to control the voltage controlled oscillator. For example, the magnitude of the difference may be adjusted to adjust the frequency of the oscillating signal produced by the voltage controlled oscillator. The charge pump may continue adjusting FILT and FILTN until the frequency of the oscillating signal matches the frequency of a reference signal.

The transistors 307C and 307D are turned on and off to adjust the voltage of FILTN, and the transistors 316A and 316B are turned on and off to adjust the voltage of FILT. To avoid the current sources 202, 206, 208, and/or 212 being turned off and/or disconnected when the transistors 307C, 307D, 316A, and/or 316B are turned off, the transistors 307A, 307B, 316C, and 316D are also provided. Generally, when the transistors 307C and 307D are turned off, the transistors 307A and 307B are turned on (and vice versa), and when the transistors 316A and 316B are turned off, the transistors 316C and 316D are turned on (and vice versa). In this manner, the transistors 307A, 307B, 316C, and 316D provide an alternate pathway for the current between the current sources 202 and 206 and between the current sources 208 and 212, which reduces noise introduced into FILT and FILTN when the transistors 307C, 307D, 316A, and 316B turn on. Due to mismatches or characteristics of the transistors 307C and 307D or of the transistors 316C and 316D, however, some of the current from the current source 202 or 208 may not travel through the current source 206 or 212, leading to a voltage buildup, which results in SENSE and/or SENSEN.

If left alone, SENSE and SENSEN may drift. As a result, when the transistors 307C and 307D turn on or when the transistors 316A and 316B turn on, the drifting of SENSE and SENSEN may introduce noise into FILT or FILTN. To reduce this noise, the control signals 222 are directed to the transistors 304 and 312 of the current sources 206 and 212. The control signals 222 reduce a different between FILTN and SENSEN and/or between FILT and SENSE. By reducing this difference or by making FILTN equal to SENSEN and/or making FILT equal to SENSE, the control signals 222 reduce noise introduced into FILT and FILTN when the transistors 307C, 307D, 316A, and 316 turn on.

Generally, FILT and FILTN may be used to control an oscillator (e.g., the voltage controlled oscillator 108 shown in FIG. 1). For example, the voltage difference between FILT and FILTN may be used to control the oscillator. In some embodiments, because noise is common to both FILT and FILTN, the difference between FILT and FILTN may remove the effects of the noise. As a result, controlling the oscillator using the voltage difference between FILT and FILTN may provide improved control of the oscillator.

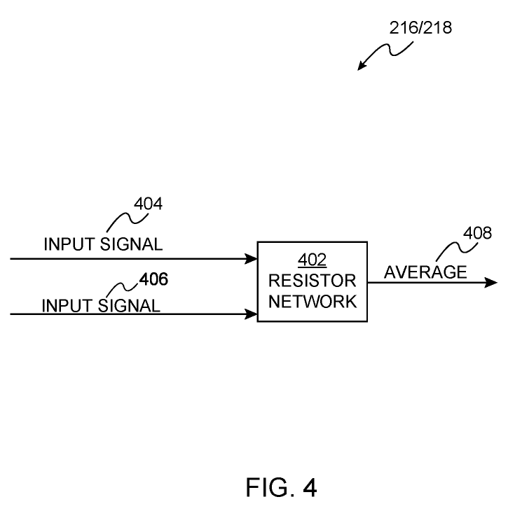

FIG. 4 illustrates an example averaging circuit 216 or 218 of the system 100 of FIG. 1. Generally, the averaging circuit 216 or 218 receives input signals and produces an output signal that is the average (e.g., average voltage or average current) of the input signals. As seen in FIG. 4, the averaging circuit 216 or 218 includes a resistor network 402. The resistor network 402 may include any number of resistors arranged in series or parallel. The resistor network 402 receives an input signal 404 and an input signal 406. The input signals 404 and 406 may be input voltages or input currents. The input signals 404 and 406 are directed through the resistor network 402, and the resistor network 402 produces an average 408 of the input signals 404 and 406. For example, the average 408 may have the average voltage or average current of the input signals 404 and 406.

As an example, the input signals 404 and 406 may be the outputs of the charge pump, FILT and FILTN. The resistor network 402 may produce the average 408, which is the average of FILT and FILTN. The average of FILT and FILTN may also be the common mode voltage of the charge pump. As another example, the input signals 404 and 406 may be the power supply of the charge pump and electrical ground. The resistor network 402 may produce the average 408, which is the average of the power supply and ground or half the power supply voltage. This average 408 may serve as the reference common mode voltage for the charge pump.

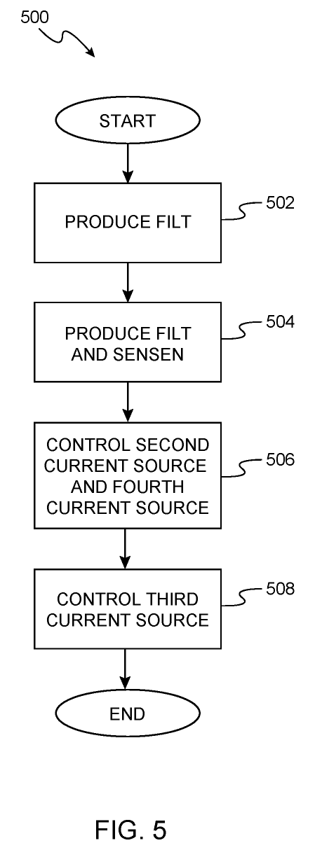

FIG. 5 is a flowchart of an example method 500 performed by the system 100 of FIG. 1. In particular embodiments, a charge pump (e.g., the charge pump 104 shown in FIG. 1) performs the method 500. By performing the method, the charge pump produces differential output signals for controlling a voltage controlled oscillator while managing the common mode voltage of the charge pump.

At 502, the charge pump produces an output signal FILT. The charge pump includes a first switching circuit that is connected to a first current source and a second current source. The first current source may be operated to direct a current from a power supply to the first switching circuit to produce FILT during a charging mode. The second current source may be operated to direct a current from FILT to electrical ground during a discharge mode. The first switching circuit includes transistor switches that may be operated to set the first switching circuit in the charging mode or the discharge mode.

At 504, the charge pump produces an output signal FILTN and an output signal SENSEN. The charge pump includes a second switching circuit that is connected to a third current source and a fourth current source. The third current source may be operated to direct a current from the power supply to the second switching circuit to produce FILTN and SENSEN during the charging mode. The fourth current source may be operated to direct a current from FILTN and SENSEN to electrical ground during the discharge mode. The second switching circuit includes transistor switches that may be operated to set the second switching circuit in the charging mode or the discharge mode.

FILT and FILTN may be complementary output signals. As a result, FILT and FILTN may move in tandem to remain centered around a common mode voltage of the charge pump. The charge pump may output FILT and FILTN, and the voltage difference between FILT and FILTN may be used to control a voltage controlled oscillator. For example, increasing the voltage difference may increase a frequency of an oscillating signal produced by the voltage controlled oscillator, while decreasing the voltage difference may decrease the frequency of the oscillating signal.

At 506, the charge pump controls the second current source and the fourth current source. The charge pump includes a first amplifier that receives FILTN and SENSEN as inputs. The first amplifier outputs a first control signal that is directed to the second current source and the fourth current source. For example, the first control signal may be directed to the gates of transistors in the second current source and the fourth current source. In this manner, the first control signal operates the second current source and the fourth current source to reduce a difference between FILTN and SENSEN, which may cause FILTN and SENSEN to match.

At 508, the charge pump controls the third current source. The charge pump includes a first averaging circuit that receives FILT and FILTN and produces an output signal that is the average (e.g., the average voltage) at FILT and FILTN, which may be the common mode voltage of the charge pump. The charge pump also includes a second averaging circuit that produces a reference common mode voltage. For example second averaging circuit may be connected to the power supply voltage and to electrical ground, and the second averaging circuit may produce the reference common mode voltage as the average of the power supply voltage and ground, which may be half the power supply voltage. The charge pump includes a second amplifier that receives the outputs of the first and second averaging circuits. The second amplifier produces a second control signal that is directed to the third current source. For example, the second control signal may be directed to the gates of the transistors in the third current source. In this manner, the second control signal operates the third current source to reduce a difference between the common mode voltage and the reference common mode voltage, which may cause the common mode voltage to match the reference common mode voltage.

The method 500 is presented as an example. In some embodiments, some of the steps of the method 500 may not be performed and/or some of the steps of the method 500 may be performed in a different order. For example, 504 may be performed before 502 in some embodiments.

In summary, a differential charge pump uses amplifiers to control gates of transistors in the current sources of the charge pump. The charge pump may include first and second current sources for a first switching circuit and third and fourth current sources for a second switching circuit. The first switching circuit produces output signals that are referred to as FILT and SENSE. The second switching circuit produces output signals that are referred to as FILTN and SENSEN, which are complementary to FILT and SENSE, respectively. The charge pump includes an amplifier that produces a control signal based on FILTN and SENSEN, and this control signal controls the gates of transistors in the second current source and the fourth current source to reduce a difference between FILTN and SENSEN. The charge pump also includes another amplifier that produces a control signal based on an average of FILT and FILTN (which may be the common mode voltage of the charge pump). This control signal controls the gates of transistors in the first current source to reduce a difference between the common mode voltage and a reference common mode voltage.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.”

While the foregoing is directed to embodiments of the present invention, other and further embodiments of the invention may be devised without departing from the basic scope thereof, and the scope thereof is determined by the claims that follow.

What is claimed is:

1. A differential charge pump comprising:
a first switching circuit arranged to produce a first output (FILT);
a second switching circuit arranged to produce a second output (FILTN) and a third output (SENSEN);
a first current source electrically connected to a first port of the first switching circuit;
a second current source electrically connected to a second port of the first switching circuit;
a third current source electrically connected to the second switching circuit;
a first amplifier arranged to control the second current source and the third current source based on FILTN and SENSEN; and
a second amplifier arranged to control the first current source based on FILT and FILTN.

2. The differential charge pump of claim 1, wherein FILT and FILTN are complementary in changes to magnitude and polarity.

3. The differential charge pump of claim 1, wherein the first amplifier is arranged to control the second current source and the third current source to reduce a difference between FILTN and SENSEN.

4. The differential charge pump of claim 1, wherein:
the second current source comprises a first plurality of transistors;
the third current source comprises a second plurality of transistors;
the first amplifier produces a fourth output based on FILTN and SENSEN; and
the fourth output of the first amplifier is electrically connected to gates of the first plurality of transistors and gates of the second plurality of transistors.

5. The differential charge pump of claim 1, wherein the second amplifier is arranged to control the first current source to maintain an average of FILT and FILTN.

6. The differential charge pump of claim 1, wherein:
the first current source comprises a first plurality of transistors;
the second amplifier produces a fourth output based on FILT and FILTN; and
the fourth output of the second amplifier is electrically connected to gates of the first plurality of transistors.

7. The differential charge pump of claim 1, further comprising a first averaging circuit arranged to produce an output that is an average of FILT and FILTN wherein the second amplifier is arranged to control the first current source based on the output of the first averaging circuit.

8. The differential charge pump of claim 7, further comprising a second averaging circuit arranged to produce a reference common mode voltage wherein the second amplifier is arranged to control the first current source to reduce a difference between the output of the first averaging circuit and the reference common mode voltage.

9. A method comprising:
producing, by a first switching circuit, a first output (FILT);
producing, by a second switching circuit, a second output (FILTN) and a third output (SENSEN);
controlling, by a first amplifier and based on FILTN and SENSEN, a first current source electrically connected to a first port of the first switching circuit and a second current source electrically connected to the second switching circuit; and
controlling, by a second amplifier and based on FILT and FILTN, a third current source electrically connected to a second port of the first switching circuit.

10. The method of claim 9, wherein FILT and FILTN are complementary in changes to mangitude and polarity.

11. The method of claim 9, wherein controlling, by the first amplifier, the first current source and the second current source reduces a difference between FILTN and SENSEN.

12. The method of claim 9, wherein:
the first current source comprises a first plurality of transistors;
the second current source comprises a second plurality of transistors;
the first amplifier produces an output based on FILTN and SENSEN; and
the output of the first amplifier is electrically connected to gates of the first plurality of transistors and gates of the second plurality of transistors.

13. The method of claim 9, wherein controlling, by the second amplifier, the third current source maintains an average of FILT and FILTN.

14. The method of claim 9, wherein:
the third current source comprises a first plurality of transistors;
the second amplifier produces a fourth output based on FILT and FILTN; and
the fourth output of the second amplifier is electrically connected to gates of the first plurality of transistors.

15. The method of claim 9, further comprising producing, by a first averaging circuit, an output that is an average of FILT and FILTN wherein controlling, by the second amplifier, the third current source is based on the output of the first averaging circuit.

16. The method of claim 15, further comprising producing, by a second averaging circuit, a reference common mode voltage wherein controlling, by the second amplifier, the third current source reduces a difference between the output of the first averaging circuit and the reference common mode voltage.

17. A phase locked loop comprising:
a phase frequency detector arranged to produce a first output based on a reference signal and an oscillating signal;
a differential charge pump comprising:
a first switching circuit arranged to produce a second output (FILT) based on the first output;
a second switching circuit arranged to produce a third output (FILTN) and a fourth output (SENSEN) based on the first output;
a first current source electrically connected to a first port of the first switching circuit;
a second current source electrically connected to a second port of the first switching circuit;
a third current source electrically connected to the second switching circuit;
a first amplifier arranged to control the second current source and the third current source based on FILTN and SENSEN; and
a second amplifier arranged to control the first current source based on FILT and FILTN; and
an oscillator arranged to produce the oscillating signal based on FILT and FILTN.

18. The phase locked loop of claim 17, wherein FILT and FILTN are complementary in changes to magnitude and polarity.

19. The phase locked loop of claim 17, wherein the first amplifier is arranged to control the second current source and the third current source to reduce a difference between FILTN and SENSEN.

20. The phase locked loop of claim 17, wherein:
the second current source comprises a first plurality of transistors;
the third current source comprises a second plurality of transistors;
the first amplifier produces a fifth output based on FILTN and SENSEN; and
the fifth output of the first amplifier is electrically connected to gates of the first plurality of transistors and gates of the second plurality of transistors.
